(19) United States
(12) Patent Application Publication
(10) Pub. No.: US 2025/0266317 A1
(43) Pub. Date: Aug. 21, 2025

(54) SEMICONDUCTOR DEVICE

(71) Applicant: FUJI ELECTRIC CO., LTD., Kawasaki-shi (JP)

(72) Inventors: Masaoki MIYAKOSHI, Matsumoto-city (JP); Ryo NOMAGUCHI, Matsumoto-city (JP)

(73) Assignee: FUJI ELECTRIC CO., LTD., Kawasaki-shi (JP)

(21) Appl. No.: 19/041,090

(22) Filed: Jan. 30, 2025

(30) Foreign Application Priority Data
Feb. 16, 2024 (JP) 2024-022249

(51) Int. Cl. H01L 23/367; H01L 23/13; H01L 23/40; H01L 23/538; H01L 25/07

(52) U.S. Cl. CPC H01L 23/3675; H01L 23/13; H01L 23/5385; H01L 25/072; H01L 23/4006

(57) ABSTRACT

A semiconductor device includes insulated circuit boards each having a rectangular shape in plan view and each including an insulating plate and a metal plate, and a heat dissipation base having a top surface having rectangular placement areas in each of which one of the insulated circuit boards is disposed via solder. The top surface has inner protrusions and outer protrusions, and each outer protrusion includes sub-protrusions. Each outer protrusion is disposed at one of four corners of placement areas that is closest to one of four corners of the top surface, and each inner protrusion is disposed at one of four corners of placement areas in which any outer protrusion is not disposed.

### CROSS-REFERENCE TO RELATED APPLICATION

This application is based upon and claims the benefit of priority of the prior Japanese Patent Application No. 2024-022249, filed on Feb. 16, 2024, the entire contents of which are incorporated herein by reference.

### BACKGROUND OF THE INVENTION

### 1. Field of the Invention

The embodiments discussed herein relate to a semiconductor device.

### 2. Background of the Related Art

Semiconductor devices include a metal base plate (heat dissipation base) and a circuit board disposed on the metal base plate via solder. The bottom surface of the circuit board is supported by protrusions formed on the metal base plate (see, for example, International Publication Pamphlets No. WO 2022/102253 and No. WO 2016/009741). In other semiconductor devices, spherical recesses are formed in the metal base plate, and a joining part is joined to the metal base plate with a brazing material (see, for example, Japanese Laid-open Patent Publication No. H05-166856). In yet other semiconductor devices, uneven patterns are formed on the top surface of the metal base plate, and a substrate is place on the metal base plate via solder (see, for example, the specification of U.S. Patent Application Publication No. 2014/0138839).

### SUMMARY OF THE INVENTION

According to an aspect, there is provided a semiconductor device including: a plurality of insulated circuit boards each having a rectangular shape and four corners in a plan view of the semiconductor device, each insulated circuit board including an insulating plate and a metal plate disposed on a bottom surface of the insulating plate; and a heat dissipation base having a top surface that has a rectangular shape in the plan view and includes a pair of first sides opposite to each other and a pair of second sides opposite to each other and perpendicular to the pair of first sides, the top surface having a plurality of rectangular placement areas in each of which a respective one of the plurality of insulated circuit boards is disposed via solder, the top surface having a plurality of protrusions respectively provided at respective ones of four corners of each of the plurality of placement areas, wherein the plurality of protrusions includes a plurality of inner protrusions and four outer protrusions, each of the four outer protrusions being made of a plurality of sub-protrusions, each of which is a protrusion among said plurality of protrusions, and the four outer protrusions are respectively disposed at respective ones of four corners of placement areas that are closest to each of the four corners of the top surface, and the plurality of inner protrusions are respectively disposed at respective ones of four corners of placement areas in which any one of the four outer protrusions is not disposed.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a first cross-sectional view of the semiconductor device of the first embodiment;

FIG. 3 is a second cross-sectional view of the semiconductor device of the first embodiment;

FIG. 4 is a plan view of semiconductor units included in the semiconductor device of the first embodiment;

FIG. 5 is a plan view of a heat dissipation base included in the semiconductor device of the first embodiment;

FIG. 6 is an enlarged cross-sectional view of an outer protrusion of the heat dissipation base included in the semiconductor device of the first embodiment;

FIG. 7 is an enlarged plan view of the outer protrusion of the heat dissipation base included in the semiconductor device of the first embodiment;

FIG. 8 is an enlarged cross-sectional view of a protrusion of a heat dissipation base included in a semiconductor device of a reference example;

FIG. 9 is an enlarged plan view of the protrusion of the heat dissipation base included in the semiconductor device of the reference example;

FIG. 10 is a plan view of another heat dissipation base included in the semiconductor device of the first embodiment;

FIG. 11 is an enlarged plan view of a protrusion on the heat dissipation base included in the semiconductor device of the first embodiment (a modification 1-1);

FIG. 12 is a plan view of the heat dissipation base included in the semiconductor device of the first embodiment (a modification 1-2);

FIG. 13 is a plan view of the heat dissipation base included in the semiconductor device of the first embodiment (a modification 1-3);

FIG. 14 is a plan view of the heat dissipation base included in the semiconductor device of the first embodiment (a modification 1-4);

FIG. 15 is a plan view of another heat dissipation base included in the semiconductor device of the first embodiment (modification 1-4);

FIG. 16 is a plan view of a heat dissipation base included in a semiconductor device of a second embodiment;

FIG. 17 is a cross-sectional view of the semiconductor device of the second embodiment; and

FIG. 18 is an enlarged cross-sectional view of a protrusion of the heat dissipation base included in the semiconductor device of the second embodiment.

### DETAILED DESCRIPTION OF THE INVENTION

Several embodiments will be described below with reference to the accompanying drawings. In the following, the terms “front surface” and “top surface” refer to the X-Y plane facing upward (in the +Z direction) in semiconductor devices 1 and 1a of the drawings. Similarly, the term “upper” refers to the upward direction (the +Z direction) of the illustrated semiconductor devices 1 and 1a. On the other hand, the terms “back surface” and “bottom surface” refer to the X-Y plane facing downward (in the −Z direction) in the illustrated semiconductor devices 1 and 1a. Similarly, the term “lower” refers to the downward direction (the −Z direction) of the illustrated semiconductor devices 1 and 1a. These terms have the same orientational relationships as described above in all drawings if needed. “High” and “upper” in position refer to upper positions (in the +Z direction) in the illustrated semiconductor devices 1 and 1a. On the other hand, “low” and “lower” in position refer to lower positions (in the −Z direction) in the illustrated semiconductor devices 1 and 1a. The terms “front surface”, “top surface”, “upper”, “back surface”, “bottom surface”, “lower”, and “lateral surface” are simply expedient expressions used to specify relative positional relationships, and are not intended to limit the technical ideas of the embodiments described herein. For example, the terms “upper” and “lower” do not necessarily imply the vertical direction to the ground surface. That is, the “upper” and “lower” directions are not defined in relation to the direction of the gravitational force. In addition, the term “major component” in the following refers to a constituent having a concentration equal to 80 vol % or higher. The phrase “substantially the same” refers to where two or more things being compared have a difference of no more than ±10%. In addition, the terms “perpendicular”, “orthogonal”, and “parallel” may also include substantially perpendicular, substantially orthogonal, and substantially parallel, as appropriate, which may include a margin of error of ±10° or less.

### (a) First Embodiment

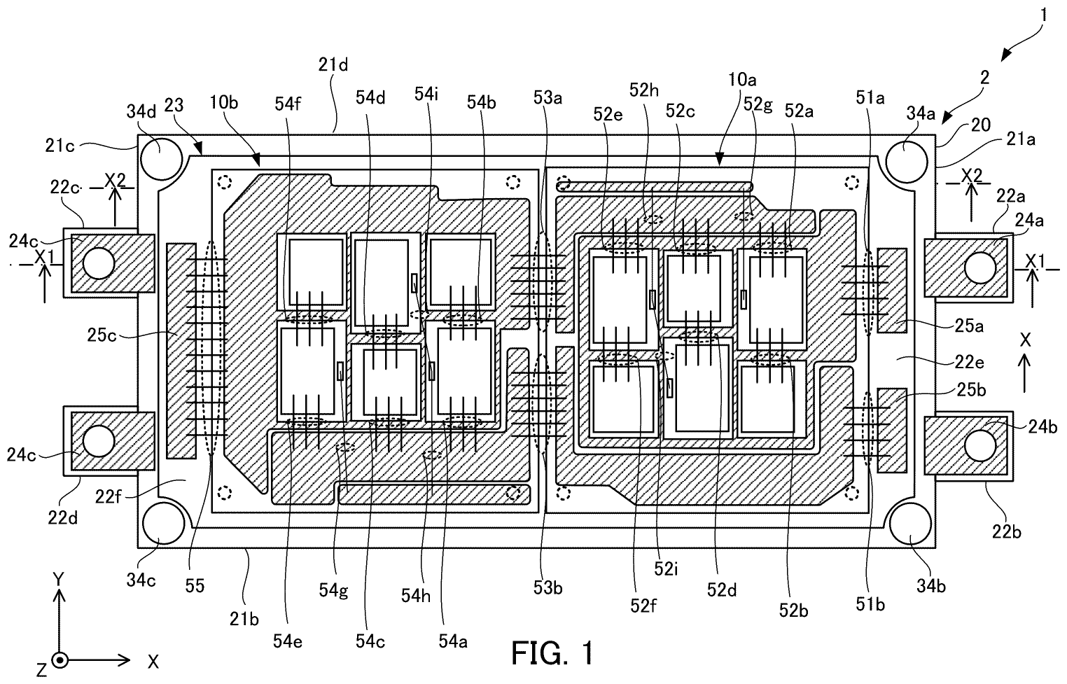

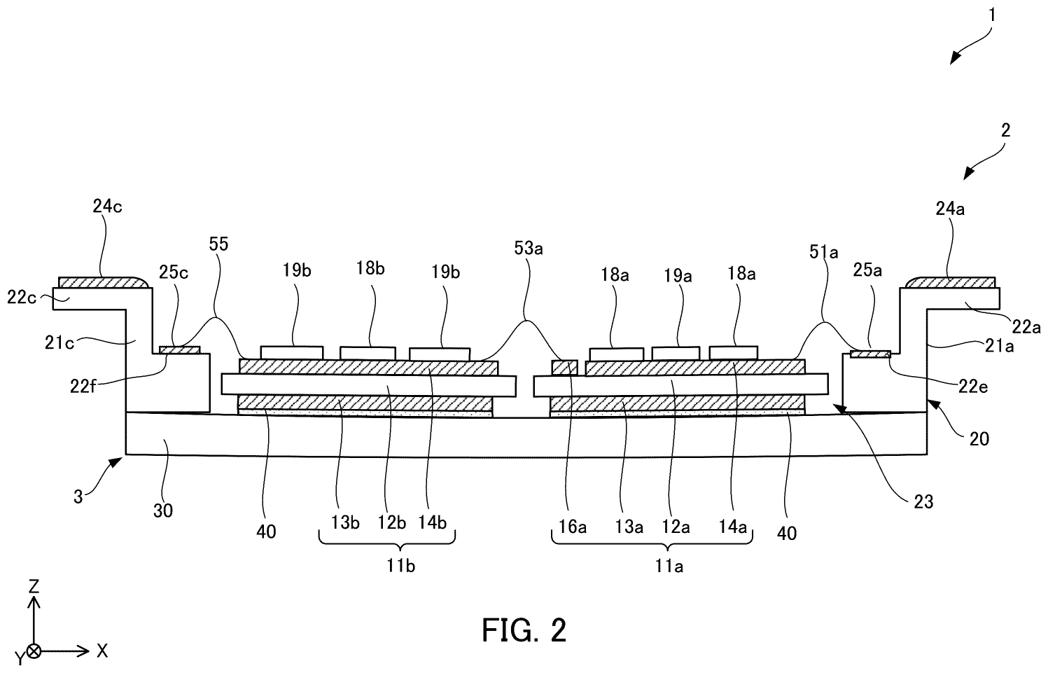

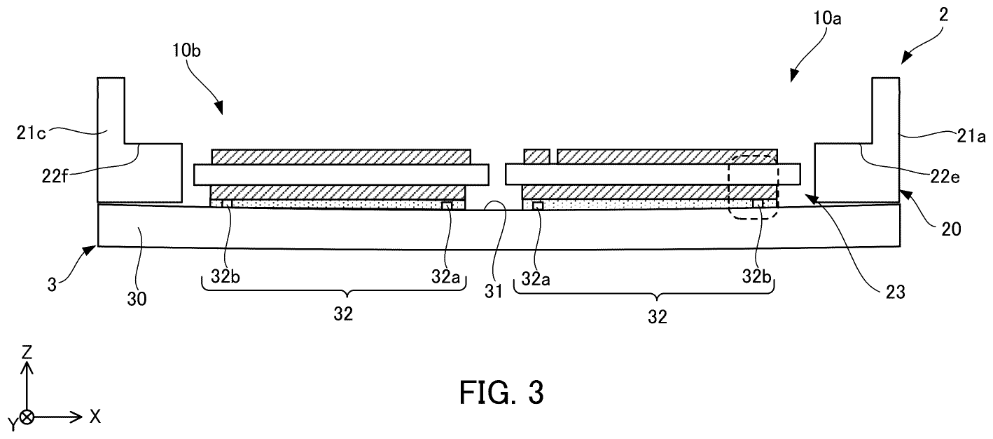

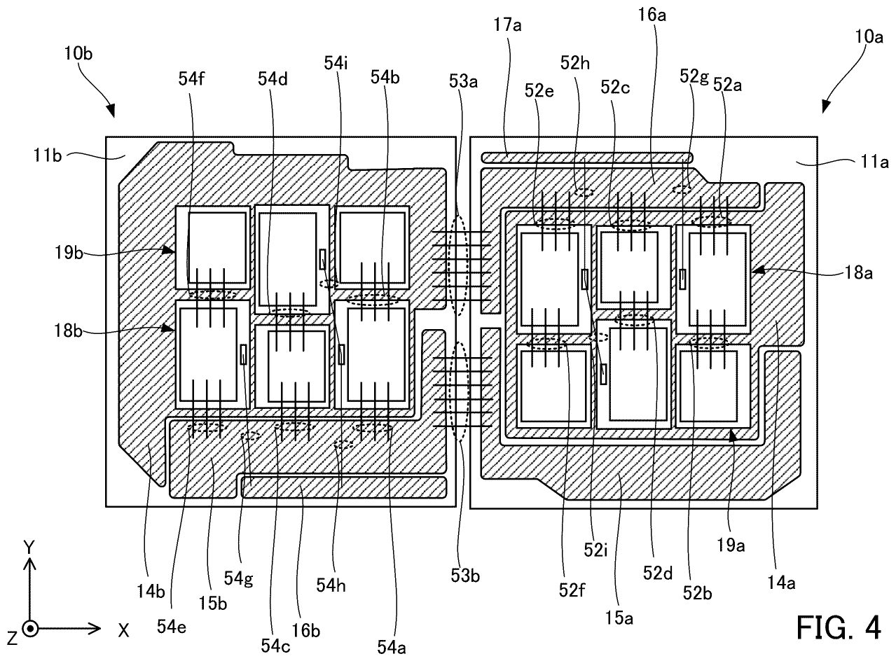

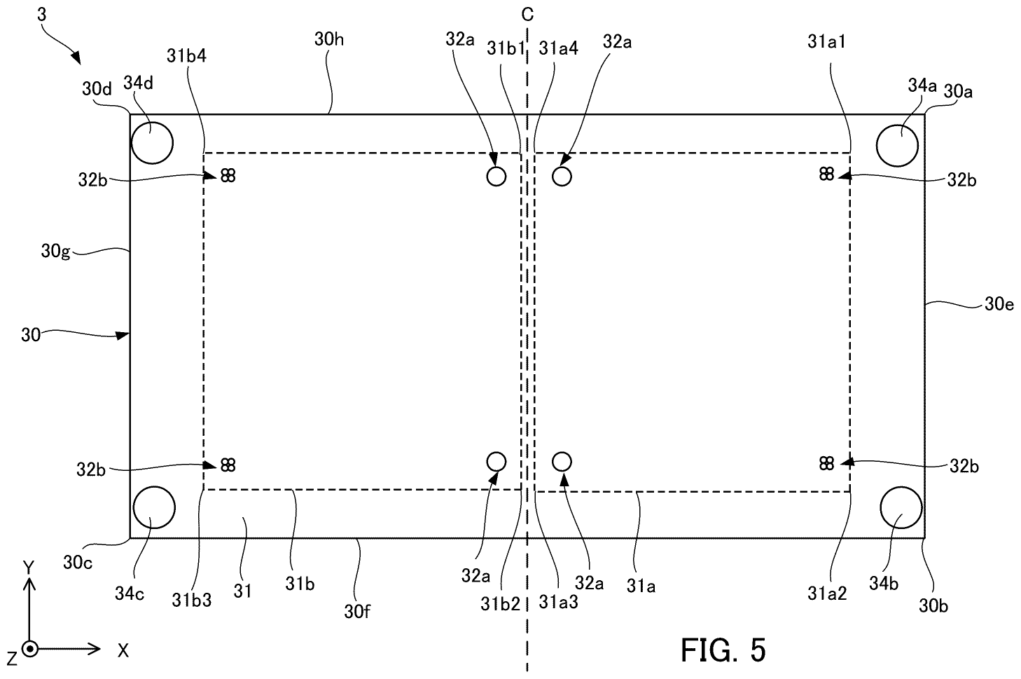

A semiconductor device according to a first embodiment is described next with reference to FIGS. 1 to 5. FIG. 1 is a plan view of the semiconductor device according to the first embodiment, and FIGS. 2 and 3 are cross-sectional views of the semiconductor device of the first embodiment. FIG. 4 is a plan view of semiconductor units included in the semiconductor device of the first embodiment, and FIG. 5 is a plan view of a heat dissipation base included in the semiconductor device of the first embodiment.

Note that a sealing member of the semiconductor device is not illustrated in FIGS. 1 to 3. The cross-sectional view of FIG. 2 is taken along dashed-dotted line X1-X1 of FIG. 1, and the cross-sectional view of FIG. 3 is taken along dashed-dotted line X2-X2 of FIG. 1. FIG. 4 illustrates semiconductor units 10a and 10b in plan view, and FIG. 5 illustrates a heat dissipation base 3 in plan view.

The semiconductor device 1 includes the semiconductor units 10a and 10b and the heat dissipation base 3 on which the semiconductor units 10a and 10b are disposed, as illustrated in FIGS. 1 to 3. The semiconductor device 1 further includes a case 2, which is disposed on the heat dissipation base 3 to house the semiconductor units 10a and 10b therein, and a sealing member (not illustrated) that seals the inside of the case 2.

The semiconductor units 10a and 10b include insulated circuit boards 11a and 11b and semiconductor chips 18a, 19a, 18b, and 19b. The insulated circuit boards 11a and 11b include insulating plates 12a and 12b, metal plates 13a and 13b, and conductive circuit patterns 14a, 15a, 16a, 17a, 14b, 15b, and 16b. The insulating plates 12a and 12b and the metal plates 13a and 13b have a rectangular shape in plan view. In addition, the insulating plates 12a and 12b and the metal plates 13a and 13b may have R- or C-chamfered corners. In plan view, the metal plates 13a and 13b are smaller in size than the insulating plates 12a and 12b, respectively, and are thus respectively formed inside the insulating plates 12a and 12b.

The insulating plates 12a and 12b may be ceramics substrates. The ceramics substrates are made of ceramics with excellent thermal conductivity. The ceramics contain, for example, aluminum oxide, aluminum nitride, or silicon nitride as a major component. As the insulated circuit boards 11a and 11b including the insulating plates 12a and 12b having such a composition, for example, direct copper bonding (DCB) boards or active metal brazed (AMB) boards may be used. The thickness of the insulating plates 12a and 12b depends on the rated voltage of the semiconductor device 1. That is, the thickness of the insulating plates 12a and 12b needs to be increased as the rated voltage of the semiconductor device 1 is higher. On the other hand, if the rated voltage of the semiconductor device 1 is lower, the thickness of the insulating plates 12a and 12b needs to be made as thin as possible to reduce the thermal resistance.

The insulating plates 12a and 12b may be resin substrates instead of ceramics substrates. The resin may be a material with low thermal resistance and high insulation capability. For example, a thermosetting resin exhibits such properties. The thermosetting resin may contain fillers. The thermal resistance of the insulating plates 12a and 12b may be further reduced by controlling the material and content of the fillers. Further, according to the fillers, the linear expansion coefficient of the insulating plates 12a and 12b and those of the metal plates 13a and 13b and the conductive circuit patterns 14a, 15a, 16a, 17a, 14b, 15b, and 16b described later may be made approximately equal. Reducing the difference in linear expansion coefficients suppresses the occurrence of warpage in the insulated circuit boards 11a and 11b due to the difference in the linear expansion coefficients even if the insulated circuit boards 11a and 11b are subject to thermal changes. In this case, the difference in linear expansion coefficients may be within a margin of error of 10% or more and 50% or less.

Such thermosetting resins include at least one of epoxy resin, cyanate resin, polyimide resin, the following: benzoxazine resin, unsaturated polyester resin, phenol resin, melamine resin, silicone resin, maleimide resin, acrylic resin, and polyamide resin. The fillers are made of at least one of oxide and nitride. Examples of the oxide include silicon oxide and aluminum oxide. Examples of the nitride include silicon nitride, aluminum nitride, and boron nitride. Furthermore, hexagonal boron nitride may be used as the fillers.

The metal plates 13a and 13b are made of a metal having excellent thermal conductivity. The material is, for example, copper, aluminum, or an alloy containing at least one of these. Here, the material contains copper. Plating may be applied to coat the surfaces of the metal plates 13a and 13b in order to provide improved corrosion resistance. In this case, a material used for plating contains nickel. Such a plating material is, for example, nickel, a nickel-phosphorus alloy, or a nickel-boron alloy.

The metal plates 13a and 13b have a rectangular shape in plan view. In addition, the metal plates 13a and 13b may have R- or C-chamfered corners. The metal plates 13a and 13b are smaller in size than the insulating plates 12a and 12b, respectively, and are respectively formed all over the bottom surfaces of the insulating plates 12a and 12b, except for their edges.

The conductive circuit patterns 14a, 15a, 16a, 17a, 14b, 15b, and 16b are made of a material with excellent electrical conductivity. The material is, for example, copper, aluminum, or an alloy containing at least one of these. Plating may be applied to the conductive circuit patterns 14a, 15a, 16a, 17a, 14b, 15b, and 16b using a material with excellent corrosion resistance. In this case, the material used for plating is, for example, nickel, a nickel-phosphorus alloy, or a nickel-boron alloy. The conductive circuit patterns 14a, 15a, 16a, 17a, 14b, 15b, and 16b on the insulating plates 12a and 12b are created by forming metal plates on the top surfaces of the insulating plates 12a and 12b and performing etching or the like on the metal plates. Alternatively, the conductive circuit patterns 14a, 15a, 16a, 17a, 14b, 15b, and 16b preliminarily cut out of a metal plate are bonded to the top surfaces of the insulating plates 12a and 12b.

The conductive circuit patterns 14a, 15a, 16a, 17a, 14b, 15b, and 16b are formed on the entire top surfaces of the insulating plates 12a and 12b except for their edges. Preferably, in plan view, edges of the conductive circuit patterns 14a, 15a, 16a, 17a, 14b, 15b, and 16b, facing the outer peripheries of the insulating plates 12a and 12b, may coincide with peripheral edges of the metal plates 13a and 13b. In this case, in the insulated circuit boards 11a and 11b, stress balance between the metal plates 13a and 13b and the bottom surfaces of the insulating plates 12a and 12b is maintained. This further reduces damage to the insulating plates 12a and 12b, such as excessive warpage and crack formation.

The conductive circuit pattern 14a is connected to an internal terminal 25a, which is a positive terminal to be described later, and is formed in the center of the insulating plate 12a, as illustrated in FIG. 4. Three semiconductor chips 18a and three semiconductor chips 19a are bonded to the conductive circuit pattern 14a via bonding members (not illustrated).

The conductive circuit pattern 15a is connected to an internal terminal 25b, which is a negative terminal to be described later, and is formed in a U-shape in plan view on the insulating plate 12a in such a manner as to surround the −Y-direction side portion of the conductive circuit pattern 14a.

The conductive circuit pattern 16a is formed in an L-shape in plan view on the insulating plate 12a at the corner in the +Y and −X directions of the conductive circuit pattern 14a. The conductive circuit pattern 16a is connected to main electrodes on the top surfaces of the semiconductor chips 18a and 19a with main current wires 52a, 52c, and 52e.

The conductive circuit pattern 17a is formed in an I-shape in plan view on the insulating plate 12a, on the +Y-direction side of the conductive circuit pattern 16a in such a manner as to run parallel to the ±X directions. The conductive circuit pattern 17a is electrically connected to control electrodes on the top surfaces of the semiconductor chips 18a with control wires 52g to 52i.

The conductive circuit pattern 14b is connected to an internal terminal 25c, which is an output terminal to be described later, and is formed to occupy two-thirds of the area from the +Y-direction edge of the insulating plate 12b, as illustrated in FIG. 4. Three semiconductor chips 18b and three semiconductor chips 19b are bonded to the conductive circuit pattern 14b via bonding members (not illustrated). The +X-direction end of the conductive circuit pattern 14b is connected to the conductive circuit pattern 16a with main current wires 53a.

The conductive circuit pattern 15b is formed in a crank shape in plan view on the insulating plate 12b in such a manner as to lie along the −Y-direction side portion of the conductive circuit pattern 14b. The conductive circuit pattern 15b is connected to main electrodes on the top surfaces of the semiconductor chips 18b and 19b with main current wires 54a, 54c, and 54e. The conductive circuit pattern 15b is also connected to the conductive circuit pattern 15a with main current wires 53b.

The conductive circuit pattern 16b is formed in an I-shape in plan view on the insulating plate 12b in such a manner as to be located on the −Y-direction side of the conductive circuit pattern 15b and lie parallel to the ±X directions. The conductive circuit pattern 16b is electrically connected to control electrodes on the top surfaces of the semiconductor chips 18b with control wires 54g to 54i.

Note that the conductive circuit patterns 14a, 15a, 16a, 17a, 14b, 15b, and 16b included in the semiconductor device 1 are merely examples, and appropriate changes may be made to the number of conductive circuit patterns, their shapes, sizes and so on, on an as-needed basis.

The semiconductor chips 18a, 18b, 19a, and 19b may be made of silicon as a major component. Alternatively, they may be made of a wide band gap semiconductor as a major component, such as silicon carbide or gallium nitride.

The semiconductor chips 18a and 18b include switching elements. The switching elements are, for example, insulated gate bipolar transistors (IGBTs) or power metal-oxide-semiconductor field-effect transistors (power MOSFETs). When the semiconductor chips 18a and 18b are IGBTs, each has a collector electrode as a main electrode (input side) on the bottom surface, and also has a gate electrode as a control electrode and an emitter electrode as a main electrode (output side) on the top surface. When the semiconductor chips 18a and 18b are power MOSFETs, each has a drain electrode as a main electrode (input side) on the bottom surface, and also has a gate electrode as a control electrode and a source electrode as a main electrode (output side) on the top surface.

The semiconductor chips 19a and 19b include diode elements. The diode elements are, for example, free wheeling diodes (FWDs) such as Schottky barrier diodes (SBDs) or P-intrinsic-N (PiN) diodes. Each of the semiconductor chips 19a and 19b has a cathode electrode as a main electrode (output side) on the bottom surface and an anode electrode as a main electrode (input side) on the top surface.

Note that, in this embodiment, the main electrodes on the top surfaces of the semiconductor chips 18a and those on the top surfaces of the semiconductor chips 19a are electrically connected to each other with main current wires 52b, 52d, and 52f. Similarly, the main electrodes on the top surfaces of the semiconductor chips 18b and those on the top surfaces of the semiconductor chips 19b are electrically connected to each other with main current wires 54b, 54d, and 54f.

Note that reverse-conducting IGBTs (RC-IGBTs) having integrated functions of both an IGBT and FWD may be used as the semiconductor chips 18a and 18b. In this case, the semiconductor chips 19a and 19b are not needed.

Alternatively, the switching elements of the semiconductor chips 18a and 18b may be power MOSFETs made of silicon carbide as a major component. In the power MOSFETS, body diodes may function as the FWDs. These semiconductor chips 18a and 18b each have, for example, a drain electrode as a main electrode (input side) on the bottom surface, and also have a gate electrode as a control electrode and a source electrode as a main electrode (output side) on the top surface. In this case, the semiconductor chips 19a and 19b are not needed.

The bonding members for joining the semiconductor chips 18a, 19a, 18b, and 19b to the conductive circuit patterns 14a and 14b are, for example, solder. The solder used is lead-free solder. The lead-free solder contains, as a major component, at least one alloy selected from, for example, a tin-silver-copper alloy, a tin-zinc-bismuth alloy, a tin-copper alloy, and a tin-silver-indium-bismuth alloy. Further, the solder may include an additive, such as nickel, germanium, cobalt, antimony, or silicon. The inclusion of the additive increases wettability, brightness, and bond strength of the solder, which results in improved reliability. The joining members may be metal sintered compacts instead of solder. The material of the metal sintered compacts may be, for example, silver, copper, or an alloy containing at least one of these.

The heat dissipation base 3 includes a heat dissipation plate 30 and multiple protrusions 32 formed on the heat dissipation plate 30. The heat dissipation plate 30 includes a rectangular top surface 31 in plan view and a long lateral surface 30f, a short lateral surface 30g, a long lateral surface 30h, and a short lateral surface 30e surrounding the top surface 31 in order on all four sides, as illustrated in FIG. 5. The long lateral surfaces 30f and 30h are parallel to each other. Similarly, the short lateral surfaces 30g and 30e are parallel to each other. The long lateral surfaces 30f and 30h are perpendicular to the short lateral surfaces 30g and 30e. The long lateral surface 30h runs at right angles to the short lateral surface 30e at a corner 30a. The short lateral surface 30e runs at right angles to the long lateral surface 30f at a corner 30b. The long lateral surface 30f runs at right angles to the short lateral surface 30g at a corner 30c. The short lateral surface 30g runs at right angles to the long lateral surface 30h at a corner 30d. Note that, in plan view, the long lateral surfaces 30f and 30h and the short lateral surfaces 30g and 30e respectively correspond to a pair of long sides (second sides) and a pair of short sides (first sides) of the top surface 31. In addition, the heat dissipation plate 30 has a center line C defined on the top surface 31. The center line C runs parallel to the paired short sides (the short lateral surfaces 30g and 30e) and passes through the midpoints of the paired long sides (the long lateral surfaces 30f and 30h).

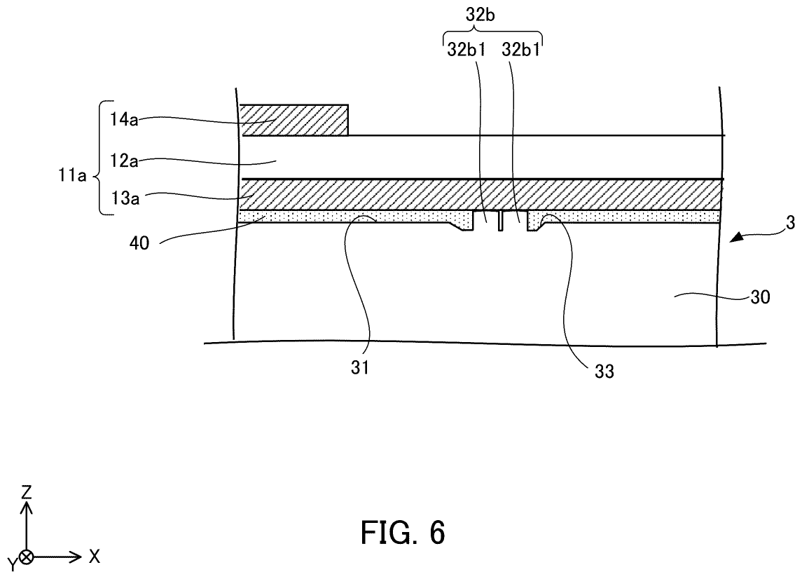

The top surface 31 of the heat dissipation plate 30 includes placement areas 31a and 31b in which the semiconductor units 10a and 10b are respectively placed via solder 40 (see FIG. 6). The placement area 31a includes corners 31a1 to 31a4. The placement area 31b includes corners 31b1 to 31b4. The placement areas 31a and 31b are included in the top surface 31, separated by the center line C. That is, the placement area 31a is included in the top surface 31 between the center line C and a first short side (the short lateral surface 30e). The placement area 31b is included in the top surface 31 between the center line C and a second short side (the short lateral surface 30g). Note that the solder 40 may be the same type as the above-described solder used as the joining members.

Fastener holes 34a to 34d are respectively formed near the corners 30a to 30d (first corners) of the heat dissipation plate 30. The fastener holes 34a to 34d penetrate the heat dissipation plate 30 near the corners 30a to 30d, respectively. The semiconductor device 1 is placed at a predetermined installation position, and then screws are inserted through the fastener holes 34a to 34d to fasten the semiconductor device 1 to the predetermined installation position.

The heat dissipation plate 30 is made of a metal with excellent thermal conductivity as a major component. The metal is, for example, copper, aluminum, or an alloy containing at least one of these. In order to provide improved corrosion resistance of the heat dissipation plate 30, plating may be applied to coat the surface of the heat dissipation plate 30. In this case, a material used for plating is, for example, nickel, a nickel-phosphorus alloy, or a nickel-boron alloy.

Note that the heat dissipation plate 30 may warp to be convex downward at the center line C. That is, in the heat dissipation plate 30, the short lateral surfaces 30e and 30g may be located above (in the +Z direction) the height of the center line C in a side view in the +Y (or −Y) direction.

The multiple protrusions 32 are formed in areas of the placement areas 31a and 31b of the top surface 31, corresponding to the outer edges of the semiconductor units 10a and 10b (the insulated circuit boards 11a and 11b). The placement areas 31a and 31b indicated by dashed lines in FIG. 5 correspond to the outer shapes of the insulated circuit boards 11a and 11b in plan view. The multiple protrusions 32 are formed, within the placement areas 31a and 31b of the top surface 31, locations corresponding to the four corners of each of the semiconductor units 10a and 10b (the insulated circuit boards 11a and 11b). The corners of the bottom surfaces of the semiconductor units 10a and 10b are supported by the multiple protrusions 32. This allows the gap between the bottom surfaces of the semiconductor units 10a and 10b and the top surface 31 of the heat dissipation plate 30 to be maintained, and the thickness of the joining members therebetween may also be kept constant.

The multiple protrusions 32 further include inner protrusions 32a and outer protrusions 32b. In each of the placement areas 31a and 31b, the inner protrusions 32a amongst the multiple protrusions 32 face the center line C, and are provided at two locations close to the center line C and respectively far from the paired short sides (the short lateral surfaces 30e and 30g). Such a pair of inner protrusions 32a may be columnar or frustum-shaped. The paired inner protrusions 32a provided in each of the placement areas 31a and 31b may be one. The columnar shape may be a cylindrical or polygonal columnar shape. The frustum shape may be a polygonal or circular frustum shape. In addition, the length of the longest width of the top surface (the diameter in the case of a circle) of each of the inner protrusions 32a may be, for example, 1.2 mm or more and 1.7 mm or less. The top surfaces of the inner protrusions 32a may bulge upward.

In each of the placement areas 31a and 31b, the outer protrusions 32b amongst the multiple protrusions 32 face each of the paired short sides (the short lateral surfaces 30e and 30g), and are provided at two locations respectively far from the center line C and close to each of the paired short sides (the short lateral surfaces 30e and 30g). In addition, the corners 31a1, 31a2, 31b3, and 31b4 (second corners) of the placement areas 31a and 31b, closer to the paired short sides (the short lateral surfaces 30e and 30g), are respectively located near the fastener holes 34a to 34d in such a manner as to face the fastener holes 34a to 34d. Accordingly, the outer protrusions 32b are also respectively located near the fastener holes 34a to 34d and face the fastener holes 34a to 34d. Each of the paired outer protrusions 32b is made up of multiple sub-protrusions. Note that FIG. 3 illustrates each outer protrusion 32b as a single protrusion so that it may be seen that the outer protrusions 32b are formed on the top surface 31 of the heat dissipation plate 30. Details of the outer protrusions 32b will be described later.

By pressing, for example, the inner protrusions 32a and the outer protrusions 32b may be formed on the top surface 31 of the heat dissipation plate 30 of the heat dissipation base 3. For example, a groove 33 is formed around each outer protrusion 32b (multiple sub-protrusions 32b1) described later by pressing. The inner protrusions 32a and the outer protrusions 32b may be the same height. Such inner protrusions 32a and outer protrusions 32b support the bottom surfaces of the semiconductor units 10a and 10b (the insulated circuit boards 11a and 11b) via the solder 40. In the illustrated example here, the outer protrusions 32b and the inner protrusions 32a have different configurations. Each of the inner protrusions 32a may be made up of multiple sub-protrusions, like the outer protrusions 32b.

The case 2 includes a housing 20, external terminals 24a to 24c, and the internal terminals 25a to 25c. The housing 20 integrally includes side walls 21a to 21d surrounding the four sides of a housing area 23 and terminal placement sections 22a to 22d. The side walls 21a and 21c correspond to the short sides, and the side walls 21b and 21d correspond to the long sides. The housing area 23 defined by the surrounding side walls 21a to 21d has a rectangular shape in plan view. The bottom surfaces of the side walls 21a to 21d are bonded to the outer edges of the top surface 31 of the heat dissipation base 3 (the heat dissipation plate 30) with an adhesive (not illustrated).

Steps 22e and 22f are provided on the inside (the housing area 23 side) of the side walls 21a and 21c, respectively. The steps 22e and 22f are approximately parallel to the top surfaces and the bottom surfaces of the side walls 21a to 21d. The steps 22e and 22f extend from the side wall 21b to the side wall 21d. The steps 22e and 22f may be located between the bottom surfaces and the top surfaces of the side walls 21a and 21c and protrude toward the housing area 23.

The terminal placement sections 22a and 22b are integrally provided on the top surface of the side wall 21a and extend outward (in the +X direction) from the side wall 21a. The terminal placement sections 22c and 22d are integrally provided on the top surface of the side wall 21c and extend outward (in the −X direction) from the side wall 21c.

The external terminal 24a is a positive terminal and is exposed from the top surface of the terminal placement section 22a. The internal terminal 25a is a positive terminal that faces the conductive circuit pattern 14a in plan view, is exposed from the top surface of the step 22e, and is electrically connected to the conductive circuit pattern 14a with main current wires 51a. The external terminal 24a and the internal terminal 25a are integrally connected inside the side wall 21a.

The external terminal 24b is a negative terminal and is exposed from the top surface of the terminal placement section 22b. The internal terminal 25b is a negative terminal and faces the conductive circuit pattern 15a in plan view. The internal terminal 25b is also exposed from the top surface of the step 22e and electrically connected to the conductive circuit pattern 15a with main current wires 51b. The external terminal 24b and the internal terminal 25b are integrally connected inside the side wall 21a.

The external terminals 24c are output terminals and are exposed from the top surfaces of the terminal placement sections 22c and 22d. The internal terminal 25c is an output terminal and faces the conductive circuit pattern 14b in plan view. The internal terminal 25c is also exposed from the top surface of the step 22f and electrically connected to the conductive circuit pattern 14b with main current wires 55. The external terminals 24c and the internal terminal 25c are integrally connected inside the side wall 21c.

The case 2 with the above-described configuration is made by integrally molding the housing 20 including therein the external terminals 24a to 24c and the internal terminals 25a to 25c. At this time, for example, the case 2 may be configured by injection molding using a thermoplastic resin. As such a thermoplastic resin, any of the following may be used: a poly phenylene sulfide (PPS) resin; a polybutylene terephthalate (PBT) resin; a polybutylene succinate (PBS) resin; a polyamide (PA) resin; and an acrylonitrile butadiene styrene (ABS) resin.

Note that the housing area 23 of the case 2 may be sealed with a sealing member (not illustrated). The sealing member may be a thermosetting resin. The thermosetting resin may be, for example, epoxy resin, phenolic resin, maleimide resin, or polyester resin; however, epoxy resin is preferred. A filler may be added to the sealing member. The filler may be ceramics with insulation properties and high thermal conductivity.

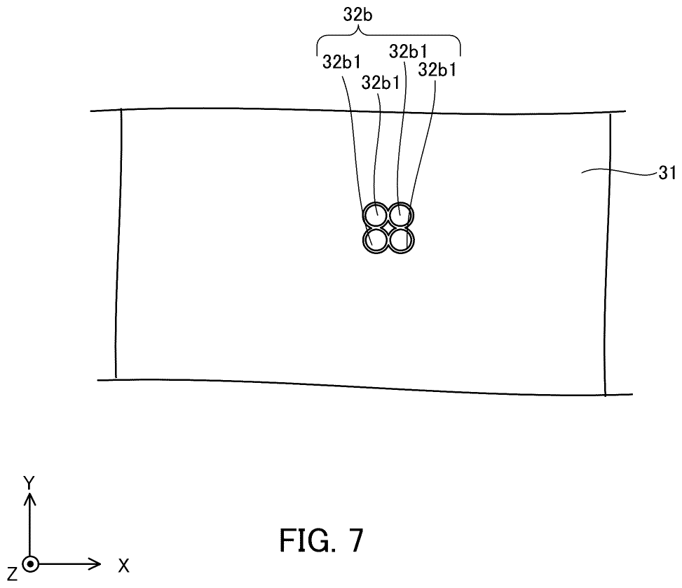

Next, the outer protrusions 32b amongst the multiple protrusions 32 are described in detail, with reference to FIGS. 6 and 7. FIG. 6 is an enlarged cross-sectional view of an outer protrusion of the heat dissipation base included in the semiconductor device of the first embodiment. FIG. 7 is an enlarged plan view of the outer protrusion of the heat dissipation base included in the semiconductor device of the first embodiment. The enlarged view of FIG. 6 depicts the outer protrusion 32b included in the protrusions 32 and its surroundings enclosed by the dashed line in FIG. 3. The plan view of FIG. 7 represents the top surface 31 of the heat dissipation base 3 (the heat dissipation plate 30) including the outer protrusion 32b of FIG. 6.

Each outer protrusion 32b is made up of multiple sub-protrusions 32b1. In the case of FIGS. 6 and 7, the outer protrusion 32b is made up of four sub-protrusions 32b1. However, the number of sub-protrusions 32b1 is not limited to four, and may be two, three, five or more. The sub-protrusions 32b1 may be columnar or frustum-shaped. The columnar shape may be a cylindrical or polygonal columnar shape. The frustum shape may be a polygonal or circular frustum shape.

The length of the longest width (the diameter in the case of FIGS. 6 and 7) of the top surface of each of the sub-protrusions 32b1 may be, for example, 0.1 mm or more and 1.0 mm or less. The top surfaces of the sub-protrusions 32b1 may also bulge upward. The spacing between the multiple sub-protrusions 32b1 in plan view may be, for example, 0.3 mm or more and 1.1 mm or less. The sizes and shapes of the multiple sub-protrusions 32b1 included in the outer protrusions 32b may be different in plan view.

The inner protrusions 32a and the outer protrusions 32b support the bottom surfaces of the semiconductor units 10a and 10b (the insulated circuit boards 11a and 11b) via the solder 40, as described above. Therefore, the outer protrusions 32b support the bottom surfaces of the semiconductor units 10a and 10b (the insulated circuit boards 11a and 11b) with the multiple sub-protrusions 32b1. In this case, the thickness of the solder 40 over the outer protrusions 32b may be sufficiently thinner than the thickness of the solder 40 over the inner protrusions 32a. The thickness of the solder 40 over the outer protrusions 32b may be substantially zero, and thus the outer protrusions 32b may be in direct contact with the bottom surfaces of the insulated circuit boards 11a and 11b. FIG. 6 depicts the case where the outer protrusion 32b is in direct contact with the bottom surface. The thickness of the solder 40 will be described later.

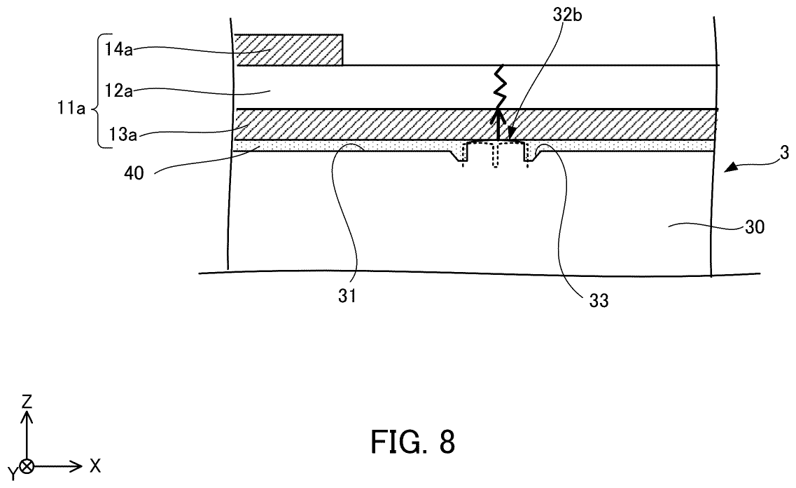

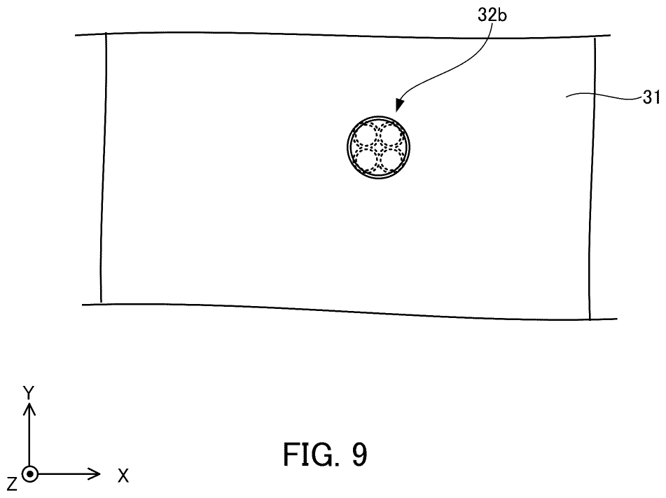

Here, outer protrusions included in a semiconductor device of a reference example given in relation to the semiconductor device 1 are described with reference to FIGS. 8 and 9. FIG. 8 is an enlarged cross-sectional view of a protrusion of a heat dissipation base included in the semiconductor device of the reference example. FIG. 9 is an enlarged plan view of the protrusion of the heat dissipation base included in the semiconductor device of the reference example. FIGS. 8 and 9 correspond to FIGS. 6 and 7, respectively. Note that, in FIGS. 8 and 9, the multiple sub-protrusions 32b1 of FIGS. 6 and 7 are indicated by dashed lines over the outer protrusions 32b of FIGS. 8 and 9.

The semiconductor device of the reference example has the same configuration as the semiconductor device 1 except for the outer protrusions 32b. The outer protrusions 32b of the semiconductor device of the reference example have the same configuration as the inner protrusions 32a.

The protrusions 32 are respectively provided at the corners of the placement areas 31a and 31b of the heat dissipation base 3, as described above. That is, in the placement areas 31a and 31b, the inner protrusions 32a are provided at the corners closer to the center line C, and the outer protrusions 32b are provided at the corners closer to the paired short sides (the short lateral surfaces 30e and 30g).

Warping occurs in the heat dissipation base 3 (the heat dissipation plate 30) due to heating and cooling during the manufacturing process of the semiconductor device. In this case, the heat dissipation base 3 may have an upward convex warp (negative warp) where the center line C is positioned above (in the +Z direction) the height of the paired short sides (the short lateral surfaces 30e and 30g). In particular, because the long sides of the heat dissipation base 3 are sufficiently longer than the short sides, the negative warp in the longitudinal direction is sufficiently larger than the negative warp in the lateral direction. Therefore, it is considered that a negative warp occurs substantially in the longitudinal direction. In anticipation of the occurrence of such a negative warp, the heat dissipation base 3 is provided with a downward convex warp (positive warp) in the longitudinal direction so that the center line C is positioned below the paired short sides (the short lateral surfaces 30e and 30g).

In manufacturing the semiconductor device of the reference example, first, the insulated circuit boards 11a and 11b are arranged, via solder plates, in the placement areas 31a and 31b of the heat dissipation base 3 with a positive warp. Then, the individual semiconductor chips 18a, 18b, 19a, and 19b are also arranged on the insulated circuit boards 11a and 11b via solder plates.

When the solder plates are heated and melted, the molten solder flows on the top surface 31 of the heat dissipation base 3 with a positive warp toward the center line C and accumulates near the center line C. Thereafter, when the molten solder is cooled and the semiconductor units 10a and 10b are bonded to the heat dissipation base 3, the thickness of the solder 40 between the semiconductor units 10a and 10b and the heat dissipation base 3 becomes thicker on the center line C side than on the side of the paired short sides (the short lateral surfaces 30e and 30g).

In the semiconductor device of the reference example, the inner protrusions 32a closer to the center line C support the bottom surfaces of the semiconductor units 10a and 10b (the insulated circuit boards 11a and 11b) via the solder 40. On the other hand, the outer protrusions 32b closer to the paired short sides (the short lateral surfaces 30e and 30g) directly support the bottom surfaces of the semiconductor units 10a and 10b (the insulated circuit boards 11a and 11b). When the bottom surfaces of the insulated circuit boards 11a and 11b of the semiconductor units 10a and 10b are in direct contact with the outer protrusions 32b, for example, if stress is generated in the semiconductor device of the reference example or if the semiconductor device is subjected to an external impact, the insulating plate 12a of the insulated circuit board 11a may be damaged starting from the outer protrusion 32b, as illustrated in FIG. 8. An example of the case where stress is generated in the semiconductor device of the reference example is when the fastener holes 34a to 34d are fastened with screws. In this case, stress may be generated internally, starting from the fastener holes 34a to 34d. In particular, stress is greater in the vicinity of the fastener holes 34a to 34d. As a result, stress is generated in the insulated circuit boards 11a and 11b, starting from the outer protrusions 32b of the protrusions 32.

When the insulating plate 12a is damaged in this manner, the insulating and dissipation properties of the insulated circuit board 11a are impaired. FIG. 8 depicts the insulated circuit board 11a; however, the insulating plate 12b of the insulated circuit board 11b is also damaged in the same fashion. This decreases the reliability of the semiconductor device of the reference example including such insulated circuit boards 11a and 11b.

On the other hand, the semiconductor device 1 described above includes the insulated circuit boards 11a and 11b each having a rectangular shape in plan view and including the insulating plates 12a and 12b and the metal plates 13a and 13b provided on the bottom surfaces of the insulating plates 12a and 12b; and the heat dissipation base 3 including the top surface 31 having a rectangular shape in plan view and including the paired short sides (the short lateral surfaces 30e and 30g) opposing each other in plan view and the placement areas 31a and 31b in which the insulated circuit boards 11a and 11b are placed via the solder 40, and the protrusions 32 provided, within the placement areas 31a and 31b of the top surface 31, at locations corresponding to the four corners of the insulated circuit boards 11a and 11b. The protrusions 32 are the inner protrusions 32a which are located near the center line C parallel to the paired short sides on the top surface 31 and far from the paired short sides, or the outer protrusions 32b which are located far from the center line C and near one of the paired short sides and are each made up of the multiple sub-protrusions 32b1.

In the above-described semiconductor device 1, the outer protrusions 32b are directly in contact with the bottom surfaces of the insulated circuit boards 11a and 11b. Because the outer protrusions 32b are each made up of the multiple sub-protrusions 32b1, stress caused by each of the sub-protrusions 32b1 on the insulated circuit boards 11a and 11b is relieved. This reduces the occurrence of damage to the insulating plates 12a and 12b of the insulated circuit boards 11a and 11b, which in turn suppresses a decrease in the insulating and heat dissipation properties of the insulated circuit boards 11a and 11b and prevents degradation of the reliability of the semiconductor device 1.

Even if the fastener holes 34a to 34d are provided near the corners 31a1, 31a2, 31b3, and 31b4 located farther from the center line C between the placement areas 31a and 31b on the heat dissipation base 3, where the semiconductor units 10a and 10b are disposed, it is also possible to reduce the occurrence of damage to the insulated circuit boards 11a and 11b. This allows a reduction in the area of the heat dissipation base 3 in plan view, which contributes to reducing the size of the semiconductor device 1.

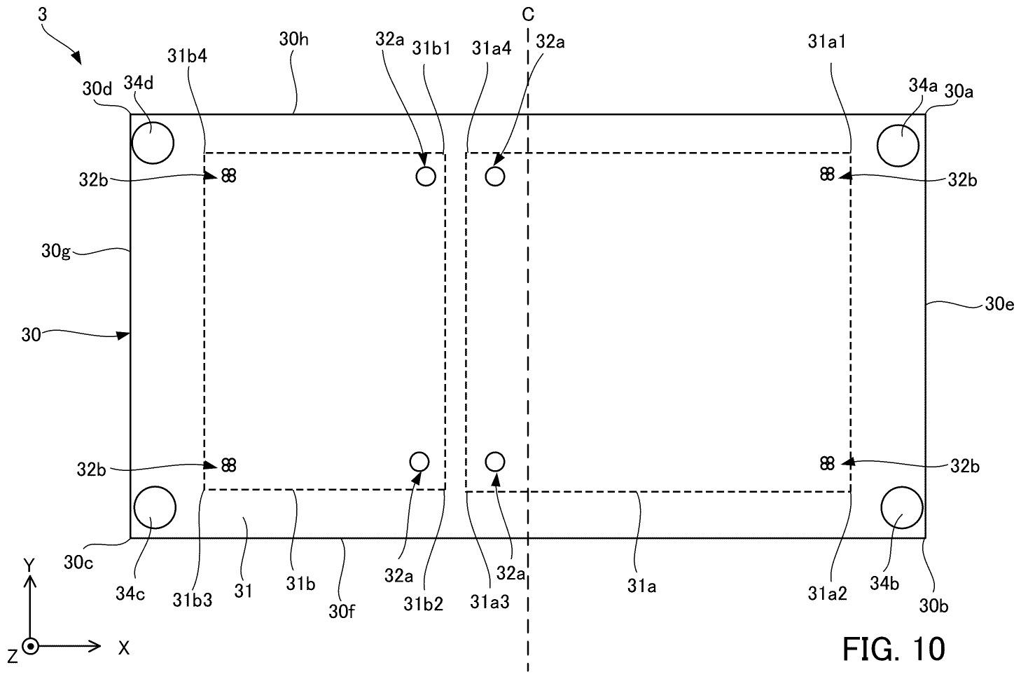

The case where the insulated circuit boards 11a and 11b are the same size has been given here as an example. That is, as depicted in FIG. 5, the placement areas 31a and 31b are provided on the top surface 31 of the heat dissipation base 3 between the center line C and the paired short sides (the short lateral surfaces 30e and 30g) with the center line C sandwiched therebetween. In addition to this example, an example of the heat dissipation base 3 with the insulated circuit boards 11a and 11b of different sizes arranged thereon is described next with reference to FIG. 10.

FIG. 10 is a plan view of another heat dissipation base included in the semiconductor device of the first embodiment. Note that, in FIG. 10, the placement areas 31a and 31b respectively corresponding to the outlines of the insulated circuit boards 11a and 11b are indicated by dashed lines on the top surface 31 of the heat dissipation base 3.

A pair of sides along the ±X directions of the insulated circuit board 11a disposed on the heat dissipation base 3 depicted in FIG. 10 is longer than those of the insulated circuit board 11b. Accordingly, the placement area 31a on the top surface 31 of the heat dissipation base 3 extends beyond the center line C toward a short side (the short lateral surface 30g). The paired sides along the ±X directions of the placement area 31b are shorter than those of the placement area 31a.

Also in this case, the four protrusions 32 in each of the placement areas 31a and 31b include the inner protrusions 32a and the outer protrusions 32b. Amongst the four protrusions 32, the paired inner protrusions 32a provided in each of the placement areas 31a and 31b are both located near the center line C and far from the paired short sides (the short lateral surfaces 30e and 30g). Note that the shape and size of the inner protrusions 32a are as described above.

Amongst the four protrusions 32, the paired outer protrusions 32b provided in each of the placement areas 31a and 31b face each of the paired short sides (the short lateral surfaces 30e and 30g) and are located near each of the paired short sides (the short lateral surfaces 30e and 30g) and far from the center line C.

Even in this case, a decrease in the insulating and heat dissipation properties of the insulated circuit boards 11a and 11b is suppressed, which thus prevents degradation of the reliability of the semiconductor device 1, as described above. Note that the following description on modifications of the semiconductor device 1 of the first embodiment refers to the case of FIG. 5; however, the same applies to the case depicted in FIG. 10.

### Modification 1-1 of First Embodiment

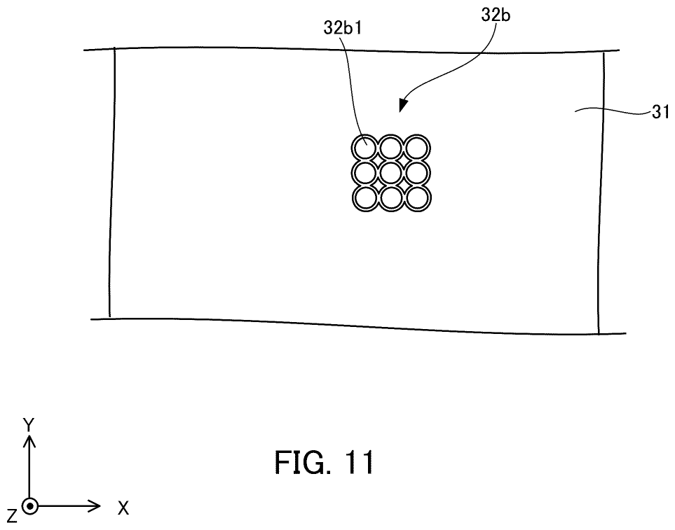

Next described are several modifications of the semiconductor device 1 of the first embodiment. First, a modification 1-1 is described with reference to FIG. 11. FIG. 11 is an enlarged plan view of protrusions on a heat dissipation base included in the semiconductor device of the first embodiment (the modification 1-1). FIG. 11 corresponds to FIG. 7 of the first embodiment.

Each of the outer protrusions 32b is made up of the multiple sub-protrusions 32b1, as described above. Preferably, the outer protrusions 32b respectively have a rectangular shape as a whole in plan view. The outer protrusions 32b each forming a rectangle as a whole in plan view provide stable support to the bottom surfaces of the insulated circuit boards 11a and 11b. The outer protrusion 32b depicted in FIGS. 6 and 7 is formed into a rectangular shape with four sub-protrusions 32b1 arranged in two rows and two columns.

In the case of the modification 1-1 represented in FIG. 11, each outer protrusion 32b is made up of nine sub-protrusions 32b1 arranged in three rows and three columns. The outer protrusions 32b of the modification 1-1 each have a greater number of sub-protrusions 32b1 than the outer protrusions 32b of FIGS. 6 and 7. Therefore, with the outer protrusions 32b of the modification 1-1, stress caused by each sub-protrusion 32b1 is further relieved compared to the case of FIGS. 6 and 7. As a result, it is possible to further reduce the impact on the insulated circuit boards 11a and 11b.

Note that the outer protrusions 32b with the sub-protrusions 32b1 arranged in two rows and two columns described in the first embodiment or in three rows and three columns described in the modification 1-1 are merely examples. That is, the outer protrusions 32b each may be made up of the sub-protrusions 32b1 arranged in n rows by m columns (n and m are integers). The number of n rows and m columns may be appropriately selected depending on, for example, the area of the bottom surfaces of the insulated circuit boards 11a and 11b.

### Modification 1-2 of First Embodiment

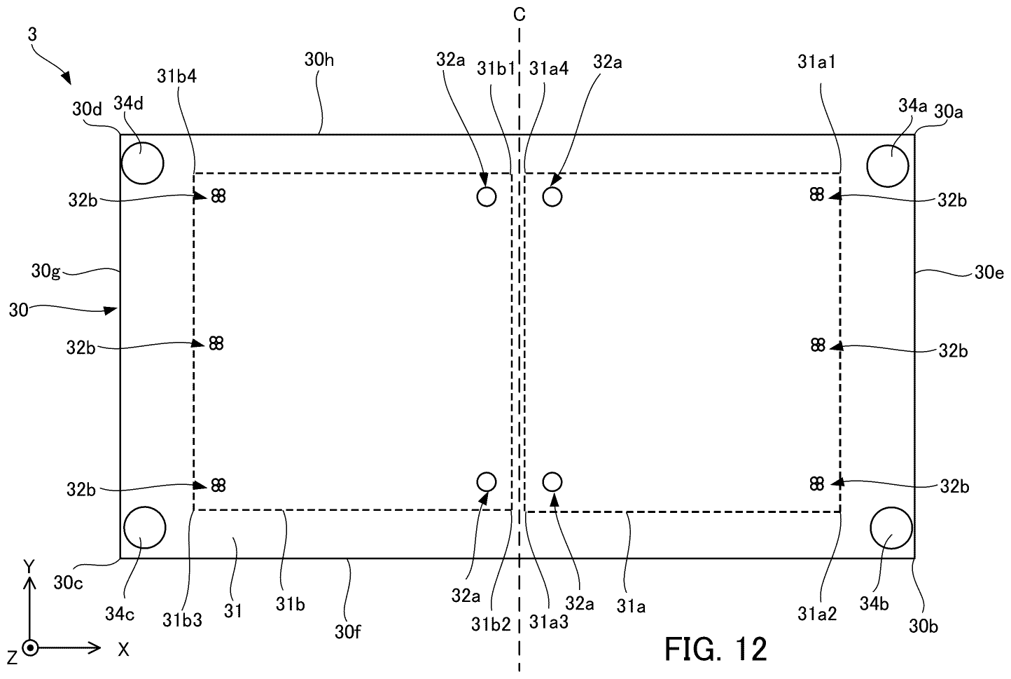

The heat dissipation base 3 of the semiconductor device 1 of a modification 1-2 is described next with reference to FIG. 12. FIG. 12 is a plan view of the heat dissipation base included in the semiconductor device of the first embodiment (the modification 1-2). Note that FIG. 12 corresponds to FIG. 5 of the first embodiment.

Amongst the multiple protrusions 32, the outer protrusions 32b are provided within the placement areas 31a and 31b in such a manner as to face the paired short sides (the short lateral surfaces 30e and 30g), as described above. The first embodiment (FIG. 5) describes, as an example, the case where the outer protrusions 32b are provided, within the placement areas 31a and 31b, at the corners 31aand 31a2 and the corners 31b3 and 31b4 closer to the paired short sides (the short lateral surfaces 30e and 30g).

In the modification 1-2, the outer protrusions 32b are also provided between the corners 31a1 and 31a2 and between the corners 31b3 and 31b4 of the placement areas 31a and 31b. In particular, FIG. 12 depicts a case where there is one outer protrusion 32b provided at the center between the corners 31a1 and 31a2 of the placement area 31a, and one at the center between the corners 31b3 and 31b4 of the placement area 31b.

Also in this case, the thickness of the solder 40 over the outer protrusions 32b is thinner than that of the solder 40 over the inner protrusions 32a, and the outer protrusions 32b may therefore be in direct contact with the bottom surfaces of the insulated circuit boards 11a and 11b. For this reason, in the modification 1-2, the outer protrusions 32b are further provided between the corners 31a1 and 31a2 and between the corners 31b3 and 31b4 of the placement areas 31a and 31b, respectively. This makes it possible to more stably support the semiconductor units 10a and 10b while suppressing impacts on the insulated circuit boards 11a and 11b.

Note that the modification 1-2 describes the case where one more outer protrusion 32b is provided between the corners 31a1 and 31a2 of the placement area 31a and between the corners 31b3 and 31b4 of the placement area 31b. The number of extra outer protrusions 32b is not limited to one, and multiple extra outer protrusions 32b may be provided on an as-needed basis. The modification 1-2 also describes the case where the single outer protrusion 32b is provided at the center between the corners 31a1 and 31a2 of the placement area 31a and at the center between the corners 31b3 and 31b4 of the placement area 31b. The extra outer protrusion 32b need not be located at the center between the corners 31a1 and 31a2 of the placement area 31a and at the center between the corners 31b3 and 31b4 of the placement area 31b, and each may be located closer to one of the corners 31a1 and 31a2 and to one of the corners 31b3 and 31b4.

### Modification 1-3 of First Embodiment

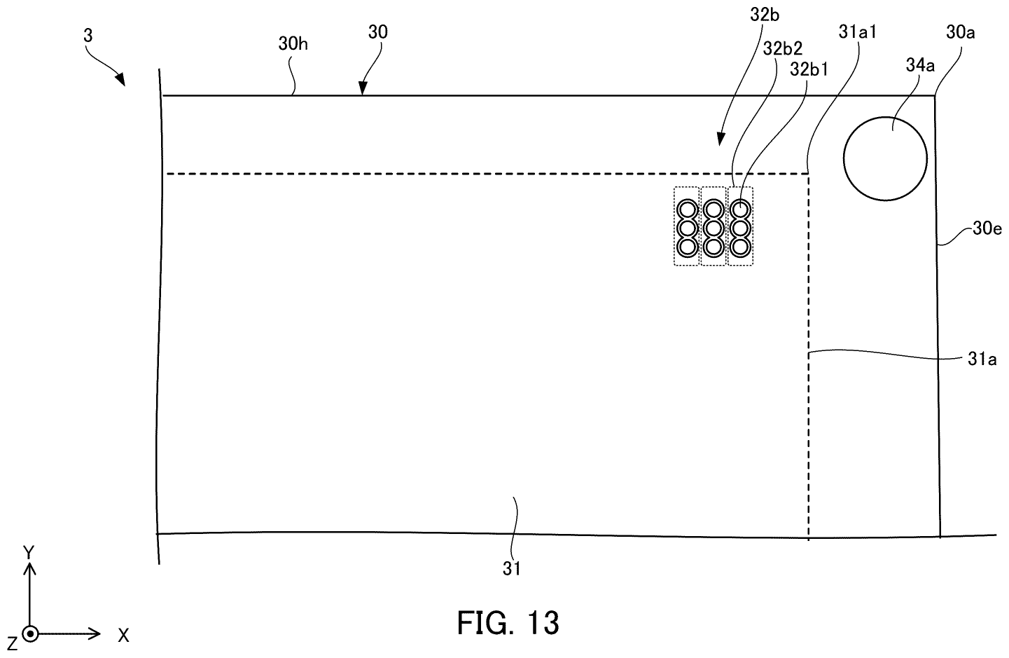

The heat dissipation base 3 of the semiconductor device 1 of a modification 1-3 is described next with reference to FIG. 13. FIG. 13 is a plan view of the heat dissipation base included in the semiconductor device of the first embodiment (the modification 1-3). Note that FIG. 13 also corresponds to FIG. 5 of the first embodiment.

According to the modification 1-3, multiple sub-protrusions 32b1 included in each of the outer protrusions 32b are arranged in a line along the paired short sides (the short lateral surfaces 30e and 30g) of the heat dissipation base 3 to form one sub-protrusion group 32b2. A plurality of such sub-protrusion groups 32b2 is provided along the paired long sides (the long lateral surfaces 30f and 30h).

In the case of FIG. 13, the outer protrusion 32b is made up of three rows of the sub-protrusion groups 32b2 arranged along the paired long sides (the long lateral surfaces 30f and 30h) of the heat dissipation base 3. In each of the sub-protrusion groups 32b2, three sub-protrusions 32b1 are arranged in a line along the paired short sides (the short lateral surfaces 30e and 30g) of the heat dissipation base 3. Note that the gap between the sub-protrusion groups 32b2 may be wider than the gap between the sub-protrusions 32b1 in each of the sub-protrusion groups 32b2.

In such outer protrusions 32b, the sub-protrusion groups 32b2 may individually be in direct contact with the bottom surfaces of the insulated circuit boards 11a and 11b. Also in this case, because each sub-protrusion group 32b2 of the outer protrusions 32b is made up of multiple sub-protrusions 32b1, stress caused by each sub-protrusion 32b1 on the insulated circuit boards 11a and 11b is relieved as in the first embodiment.

The heat dissipation base 3 is warped downward (along the longitudinal direction) at the center line C, as described above. The insulated circuit boards 11a and 11b of the semiconductor units 10a and 10b joined to the heat dissipation base 3 warped in this manner may also warp together with the heat dissipation base 3 due to heating and cooling.

The multiple rows of the sub-protrusion groups 32b2 of the outer protrusions 32b are arranged along the paired long sides (the long lateral surfaces 30f and 30h) of the heat dissipation base 3. Therefore, each row of the sub-protrusion groups 32b2 of the outer protrusions 32b is able to follow the warping of the heat dissipation base 3 and the insulated circuit boards 11a and 11b to thereby more stably support the bottom surfaces of the insulated circuit boards 11a and 11b.

Note that, in the modification 1-3, the outer protrusions 32b are provided along the paired long sides (the long lateral surfaces 30f and 30h) so as to follow the warping direction of the heat dissipation base 3. Therefore, depending on the warping direction of the heat dissipation base 3, the outer protrusions 32b of the modification 1-3 need not be provided along the paired long sides (the long lateral surfaces 30f and 30h).

The sub-protrusion groups 32b2 of the outer protrusions 32b of the modification 1-3 may be arranged in a single row or in multiple rows along the paired long sides (the long lateral surfaces 30f and 30h). When the sub-protrusion groups 32b2 are provided in multiple rows, they may be arranged in a single row in the ±X directions, or may be arranged offset in the ±Y directions. The number of sub-protrusions 32b1 included in each sub-protrusion group 32b2 is not limited to three, and may be two, four or more sub-protrusions 32b1 arranged in a row. Furthermore, the number of sub-protrusions 32b1 included in each sub-protrusion group 32b2 may vary. Such outer protrusions 32b may be provided at the corners 31a1 and 31a2 and the corners 31b3 and 31b4 of the placement areas 31a and 31b on the top surface 31 of the heat dissipation base 3, as well as in multiple locations between the corners 31a1 and 31a2 and between the corners 31b3 and 31b4, as in the modification 1-2.

### Modification 1-4 of First Embodiment

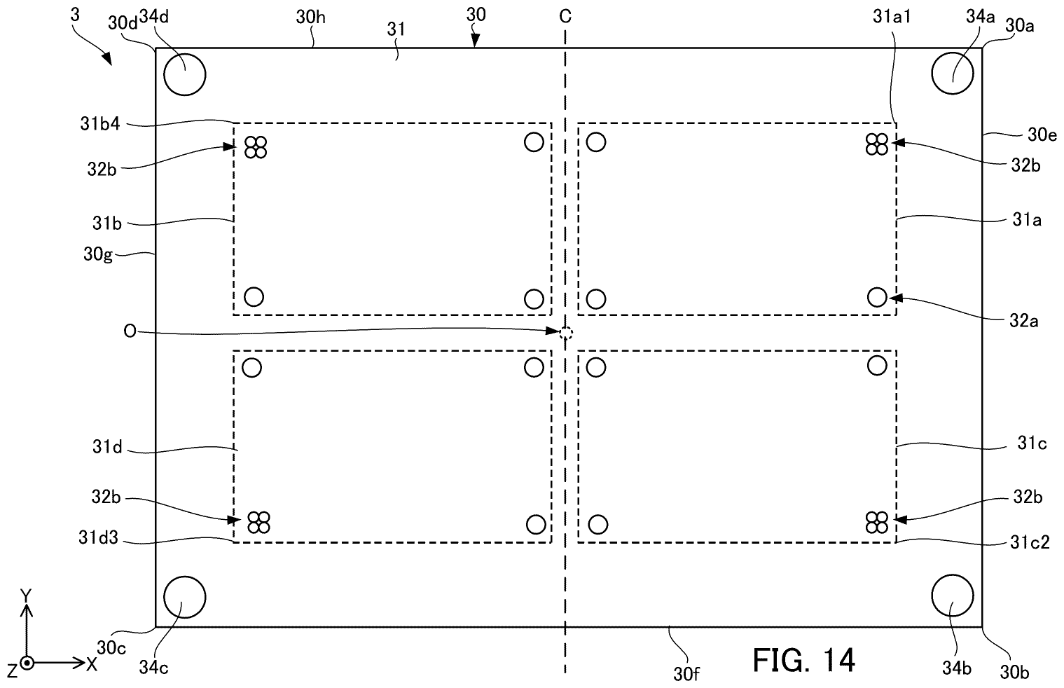

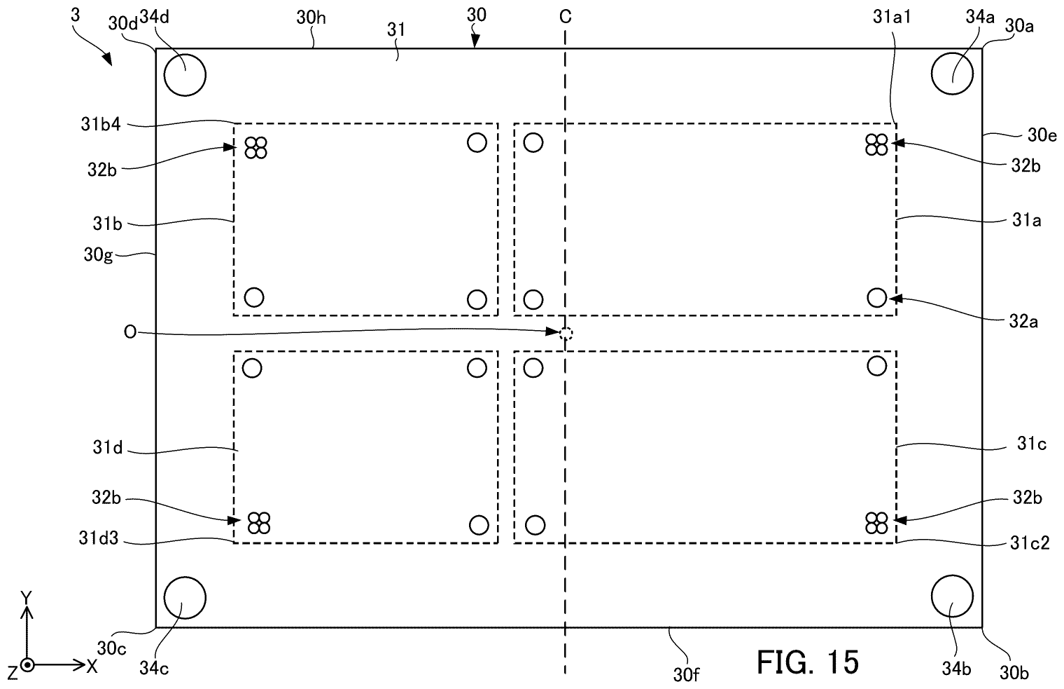

In a modification 1-4 of the first embodiment, the semiconductor device 1 of the first embodiment includes one more pair of the semiconductor units 10a and 10b, that is, making a total of four semiconductor units. The heat dissipation base 3 used in this case is described with reference to FIGS. 14 and 15. FIG. 14 is a plan view of a heat dissipation base included in the semiconductor device of the first embodiment (the modification 1-4). FIG. 15 is a plan view of another heat dissipation base included in the semiconductor device of the first embodiment (the modification 1-4). Note that FIGS. 14 and 15 correspond to FIGS. 5 and 10, respectively, of the first embodiment. The placement areas 31a and 31b and placement areas 31c and 31d indicated by dashed lines in FIGS. 14 and 15 correspond to the outlines of insulated circuit boards in plan view.

On the top surface 31 of the heat dissipation base 3 of the modification 1-4, the placement areas 31c and 31d are further provided in addition to the placement areas 31a and 31b. Therefore, the placement areas 31a to 31d are provided in two rows and two columns on the top surface 31 of the heat dissipation base 3.

On the aforementioned top surface 31 of the heat dissipation base 3, the outer protrusions 32b are individually provided, within the placement areas 31a to 31d, at the corners 31a1, 31b4, 31c2, and 31d3 located closer to the paired short sides (the short lateral surfaces 30e and 30g) and near (facing) the fastener holes 34a to 34d.

Compared to the heat dissipation base 3 of the first embodiment, the paired long sides (the long lateral surfaces 30f and 30h) of the heat dissipation base 3 of the modification 1-4 are short in length, and are close in length to the paired short sides (the short lateral surfaces 30e and 30g). When heated, the heat dissipation base 3 with this configuration may warp in the lateral direction as well as in the longitudinal direction. In view of this, the heat dissipation base 3 of the modification 1-4 is formed in advance into a bowl-shaped warp with a center point O at the bottom. That is, the corners 30a to 30d of the heat dissipation base 3 are located above (in the +Z direction) the height of the center point O.

The semiconductor units are placed via solder plates in the placement areas 31a to 31d of the heat dissipation base 3 with such warping, and when the solder plates melt, the molten solder moves to the center point O of the top surface 31 of the heat dissipation base 3 and accumulates in a circular or elliptical shape centered on the center point O in plan view. In this condition, it is expected that, if the semiconductor units are joined to the placement areas 31a to 31d of the heat dissipation base 3 with the solder 40, almost no solder 40 remains between the corners 31a1, 31b4, 31c2, and 31d3 of the placement areas 31a to 31d of the heat dissipation base 3 and the bottom surfaces of the semiconductor units (the insulated circuit boards). Also, there is a risk that stress caused by fastening screws becomes large near the fastener holes 34a to 34d, as described above.

For this reason, on the top surface 31 of the heat dissipation base 3 with the four placement areas 31a to 31d arranged in two rows and two columns, the outer protrusions 32b are individually provided, within the placement areas 31a to 31d, at the corners 31a1, 31b4, 31c2, and 31d3 near (facing) the fastener holes 34a to 34d.

Therefore, also in the semiconductor device 1 of the modification 1-4, the outer protrusions 32b are in direct contact with the bottom surfaces of the insulated circuit boards, at locations corresponding to the corners 31a1, 31b4, 31c2, and 31d3 of the placement areas 31a to 31d, as in the first embodiment. Each of the outer protrusions 32b is made up of multiple sub-protrusions 32b1, and stress caused by each of the sub-protrusions 32b1 on the insulated circuit boards is relieved. This reduces the occurrence of damage to the insulating plates of the insulated circuit boards, which in suppresses a decrease in the insulating and heat turn dissipation properties of the insulated circuit boards and prevents degradation of the reliability of the semiconductor device 1 of the modification 1-4.

Also in the case of setting the four placement areas 31a to 31d in two rows and two columns on the top surface 31 of the heat dissipation base 3, the placement areas 31a to 31d may have different sizes. For example, the placement areas 31a to 31d on the top surface 31 of the heat dissipation base 3 depicted in FIG. 15 have sizes according to the insulated circuit boards. That is, the placement areas 31a and 31c extend beyond the center line C toward the short side (the short lateral surface 30g). The paired long sides of the placement areas 31b and 31d are shorter than those of the placement areas 31a and 31c.

Also in this case, the occurrence of damage to the insulating plates of the insulated circuit boards is reduced, which in turn suppresses a decrease in the insulating and heat dissipation properties of the insulated circuit boards, as in the case of FIG. 14. This therefore prevents degradation of the reliability of the semiconductor device 1.

### (b) Second Embodiment

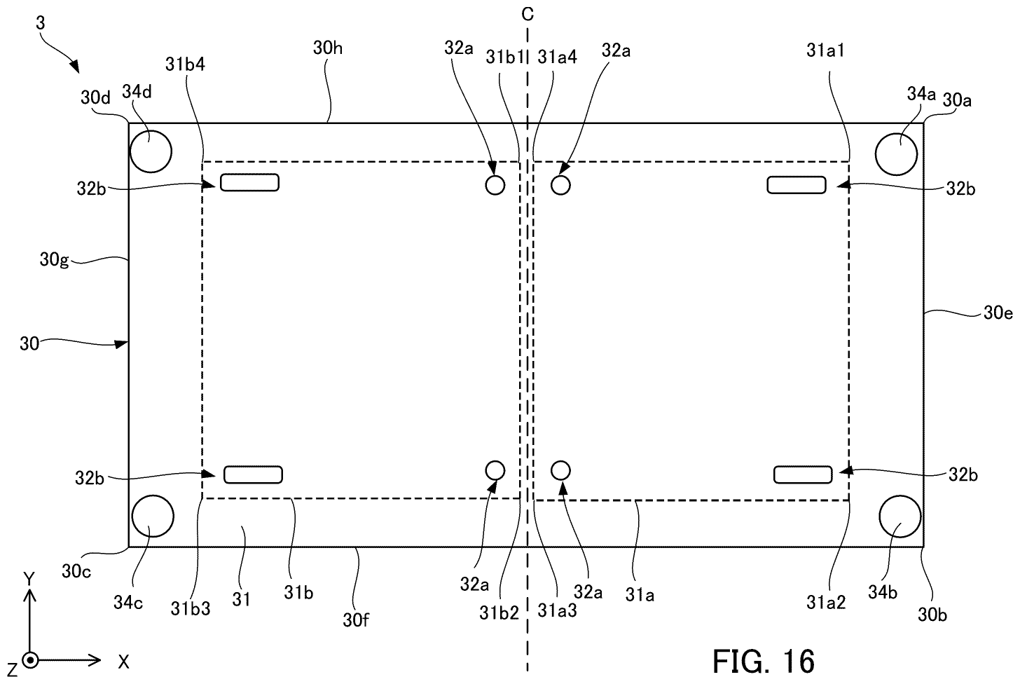

The semiconductor device 1a of a second embodiment differs from the semiconductor device 1 of the first embodiment in the outer protrusions 32b of the heat dissipation base 3. The semiconductor device 1a has the same configuration as the semiconductor device 1 except for the outer protrusions 32b. The semiconductor device 1a is described next with reference to FIGS. 16 to 18. Note that the case of the heat dissipation base 3 (except for the outer protrusions 32b) depicted in FIG. 5 is described here; however, the same applies to the cases of FIGS. 10, 14, and 15.

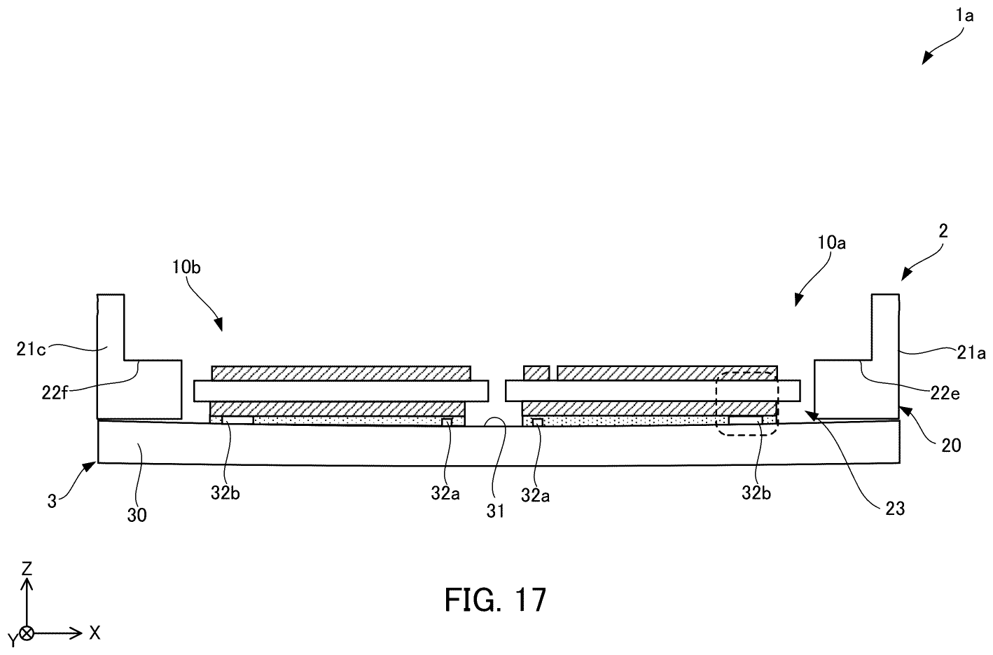

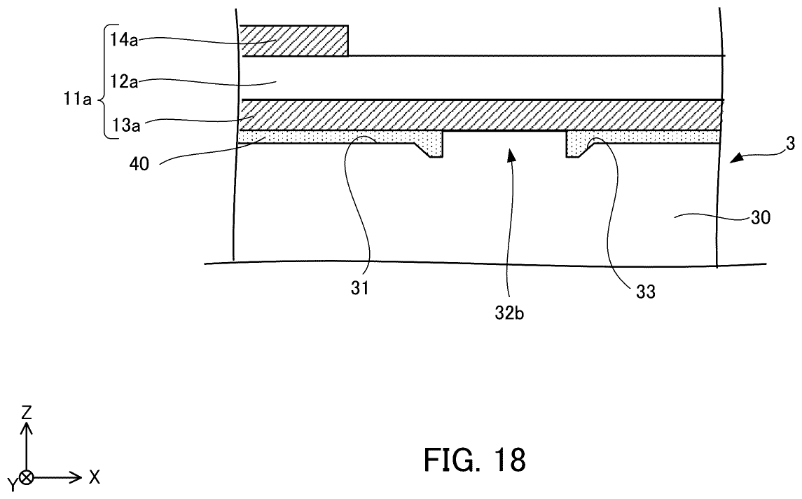

FIG. 16 is a plan view of a heat dissipation base included in the semiconductor device of the second embodiment. FIG. 17 is a cross-sectional view of the semiconductor device of the second embodiment. FIG. 18 is an enlarged cross-sectional view of a protrusion of the heat dissipation base included in the semiconductor device of the second embodiment. Note that FIG. 16 corresponds to FIG. 5 of the first embodiment, and depicts the heat dissipation base 3 of the semiconductor device 1a in plan view. FIG. 17 corresponds to FIG. 3 of the first embodiment, and depicts the semiconductor device 1a at a position of dashed-dotted line X2-X2 of FIG. 1 in a cross-section. FIG. 18 corresponds to FIG. 6 of the first embodiment, and depicts an enlarged view of the area enclosed by the dashed line in FIG. 17.

The heat dissipation base 3 of the semiconductor device 1a also includes the heat dissipation plate 30 and the multiple protrusions 32 formed on the heat dissipation plate 30, as in the first embodiment. The fastener holes 34a to 34d penetrating the heat dissipation plate 30 are also formed near the corners 30a to 30d, respectively, of the heat dissipation plate 30. The corners 30a to 30d of the heat dissipation plate 30 face the corners 31a1, 31a2, 31b3, and 31b4, respectively, of the placement areas 31a and 31b.

The multiple protrusions 32 are provided, on the top surface 31, at locations (the corners 31a1, 31a2, 31a3, 31a4, 31b1, 31b2, 31b3, and 31b4) in the placement areas 31a and 31b, corresponding to the outer edges (corners) of the semiconductor units 10a and 10b (the insulated circuit boards 11a and 11b), as in the first embodiment.

The multiple protrusions 32 further include the inner protrusions 32a and the outer protrusions 32b. In each of the placement areas 31a and 31b, the inner protrusions 32a amongst the multiple protrusions 32 respectively face the center line C, and are provided at locations close to the center line C and respectively far from the paired short sides (the short lateral surfaces 30e and 30g). In each of the placement areas 31a and 31b, the outer protrusions 32b amongst the multiple protrusions 32 face each of the paired short sides (the short lateral surfaces 30e and 30g), and are provided at locations far from the center line C and close to each of the paired short sides (the short lateral surfaces 30e and 30g).

Note that the outer protrusions 32b of the second embodiment have a rectangular shape in plan view, as illustrated in FIGS. 16 and 17. Specifically, a pair of long sides of each of the outer protrusions 32b extends along the paired long sides (the long lateral surfaces 30f and 30h) and are longer than a pair of short sides. The paired short sides of each of the outer protrusions 32b may be, for example, 0.1 mm or more and 1 mm or less. The paired long sides of each of the outer protrusions 32b may be, for example, 2.5 times or more and 5 times or less than the paired short sides. The thickness of the outer protrusions 32b may be the same as that of the outer protrusions 32b of the first embodiment.

When the semiconductor units 10a and 10b are respectively joined to the placement areas 31a and 31b of the aforementioned heat dissipation base 3 with the solder 40, for example, the bottom surface of the insulated circuit board 11a is directly supported by the outer protrusions 32b, as depicted in FIG. 18. The outer protrusions 32b extending along the paired long sides (the long lateral surfaces 30f and 30h) of the heat dissipation base 3 in this manner follow warping of the heat dissipation base 3 having a downward convex warp about the center line C to support the insulated circuit boards 11a and 11b. The support of the insulated circuit boards 11a and 11b is maintained by the entire top surfaces of the outer protrusions 32b, and stress caused by the outer protrusions 32b on the insulated circuit boards 11a and 11b is relieved. This reduces the occurrence of damage to the insulating plates 12a and 12b of the insulated circuit boards 11a and 11b, which in turn suppresses a decrease in the insulating and heat dissipation properties of the insulated circuit boards 11a and 11b and prevents degradation of the reliability of the semiconductor device 1a.

Also in the second embodiment, the outer protrusions 32b may be provided between the corners 31a1 and 31a2 and between the corners 31b3 and 31b4 of the placement areas 31a and 31b of the heat dissipation base 3, as in the modification 1-2 of the first embodiment.

The shape of each of the outer protrusions 32b is not limited to a rectangular shape as long as it is able to follow warping of the heat dissipation base 3 having a downward convex warp about the center line C. For example, the outer protrusions 32b may be an ellipse whose semimajor axis extends along the paired long sides (the long lateral surfaces 30f and 30h) in plan view.

According to an aspect, it is possible to reduce the occurrence of damage to the insulated circuit boards and prevent degradation of the reliability.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a plurality of insulated circuit boards each having a rectangular shape and four corners in a plan view of the semiconductor device, each insulated circuit board including an insulating plate and a metal plate disposed on a bottom surface of the insulating plate; and
a heat dissipation base having a top surface that has a rectangular shape in the plan view and includes a pair of first sides opposite to each other and a pair of second sides opposite to each other and perpendicular to the pair of first sides, the top surface having a plurality of rectangular placement areas in each of which a respective one of the plurality of insulated circuit boards is disposed via solder, the top surface having a plurality of protrusions respectively provided at respective ones of four corners of each of the plurality of placement areas, wherein
the plurality of protrusions includes a plurality of inner protrusions and four outer protrusions, each of the four outer protrusions being made of a plurality of sub-protrusions, each of which is a protrusion among said plurality of protrusions, and
the four outer protrusions are respectively disposed at respective ones of four corners of placement areas that are closest to each of the four corners of the top surface, and
the plurality of inner protrusions are respectively disposed at respective ones of four corners of placement areas in which any one of the four outer protrusions is not disposed.

2. The semiconductor device according to claim 1, wherein:
each of the plurality of insulated circuit boards includes two of the inner protrusions and two of the four outer protrusions.

3. The semiconductor device according to claim 2, wherein:
the heat dissipation base has four fastener holes penetrating therethrough, and respectively provided at four corners thereof.

4. The semiconductor device according to claim 3, wherein:
two of the plurality of placement areas are disposed between the pair of first sides, and
each of the two placement areas further includes an outer protrusion at one of sides thereof that is closest to a corresponding one of the first sides of the top surface.

5. The semiconductor device according to claim 4, wherein:
more than one of the plurality of insulated circuit boards are provided on the top surface of the heat dissipation base along one of the second sides, and
the four outer protrusions are respectively provided at insulated circuit boards that each face one of the second sides of the top surface at corner portions thereof that each are closest to one of the four corners of the top surface.

6. The semiconductor device according to claim 1, wherein:
the first sides are short sides of the heat dissipation base that are relatively shorter than the second sides, and
the plurality of sub-protrusions included in each of the four outer protrusions are arranged in a line along a corresponding one of the first sides.

7. The semiconductor device according to claim 6, wherein:
the plurality of sub-protrusions included in each of the four outer protrusions are arranged in a plurality of lines that are respectively provided with a gap in a direction of the second sides.

8. A semiconductor device, comprising:
a plurality of insulated circuit boards each having a rectangular shape in a plan view of the semiconductor device, each insulated circuit board including an insulating plate and a metal plate disposed on a bottom surface of the insulating plate; and
a heat dissipation base having a top surface that has a rectangular shape in the plan view and includes a pair of long sides, a pair of short sides that are perpendicular to the long sides, the top surface having a plurality of rectangular placement areas in each of which a respective one of the plurality of insulated circuit boards is disposed via solder, and a plurality of protrusions respectively provided at respective ones of four corners of each of the plurality of placement areas, wherein
each of the plurality of protrusions is either one of an inner protrusion or an outer protrusion, the inner protrusion being positioned closer to a center line parallel to the pair of short sides on the top surface than is a closer one of the pair of short sides, the outer protrusion being positioned farther from the center line than is a closer one of the pair of short sides and facing the closer one of the pair of short sides and extending in a direction of the pair of long sides.

9. The semiconductor device according to claim 8, wherein:
the heat dissipation base has four fastener holes penetrating therethrough, respectively provided at four corners thereof.
